(19) United States
(12) Patent Application Publication
(10) Pub. No.: US 2007/0218201 A1
(43) Pub. Date: Sep. 20, 2007

(54) Continuous Thermal Vacuum Deposition Device and Method

(75) Inventors: Lutz Gottsman, Kleinroehrsdorf (DE); Ulf Seyfert, Dresden (DE); Bernd-Dieter Wenzel, Grossharthau-Buehlau (DE)

Correspondence Address: HESLIN ROTHENBERG FARLEY & MESITI PC, 5 COLUMBIA CIRCLE, ALBANY, NY, 12203, US

(73) Assignee: VON ARDENNE ANLAGENTECHNIK GMBH, Dresden (DE)

(21) Appl. No.: 11/568,335

(22) PCT Filed: Apr. 16, 2005
(86) PCT No.: PCT/DE05/00700

§ 371 Date: Feb. 23, 2007

(30) Foreign Application Priority Data
Aug. 27, 2004 (DE) 10 2004 041 855.1
Apr. 27, 2004 (DE) 10 2004 020 841.7

(51) Int. Cl. C23C 14/56

(52) U.S. Cl. 427/248.1; 118/718

(57) ABSTRACT

A coating method is provided for thermally vacuum-depositing a continuously conveyed substrate that moves within a deposition channel by vaporizing solid or liquid coating materials and vapor-depositing the vaporized coating material onto the substrate in a deposition device. In order to create a coating conveyed substrate, in which accessibility to the vaporization device is improved while the processes taking place in the deposition chamber and the vaporization device can be controlled independently of each other, at least one evaporation device is located outside the deposition chamber and delivery of steam between the evaporator and the deposition channel is regulated.

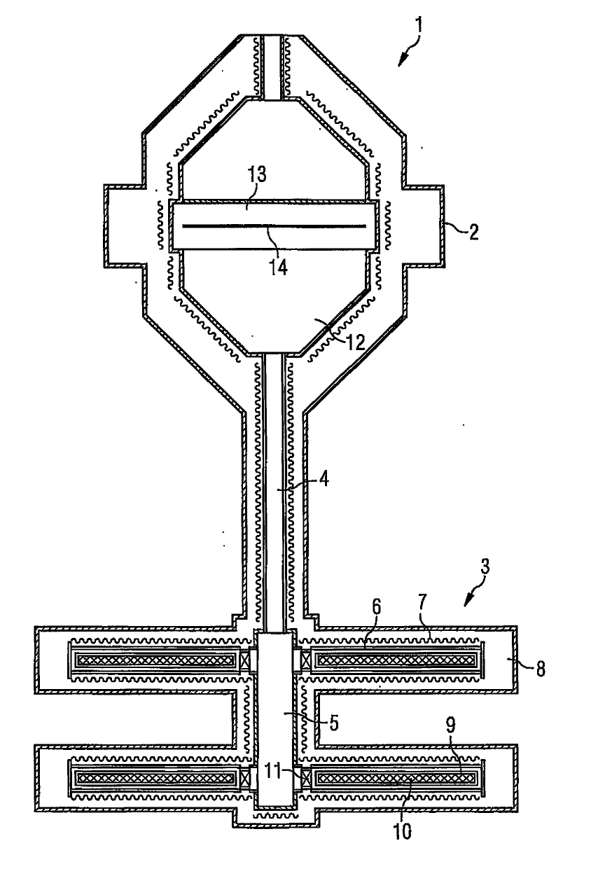

The invention relates to a coating method for thermally vacuum-depositing a continuously conveyed substrate that moves within a deposition channel by vaporizing solid or liquid coating materials and vapor-depositing the vaporized coating material onto the substrate in a deposition device.

Furthermore, the invention relates to a coating device for the vacuum-depositing of a continuously conveyed substrate with a deposition chamber, in which a deposition channel enclosing the substrate is located, and with a vaporization device connected with the deposition channel.

Coating systems and coating methods for thermal vapor coating in a vacuum are well known. For example, EP 0 735 157 reveals a method for the vaporization of magnesium (Mg). The method involves a source of Mg in a receptacle with a narrow opening and with a reflector plate located outside the opening. The receptacle is heated to between 670° C. and 770° C., at which point the source of Mg has melted and the Mg is thus vaporized. When it escapes, clusters and splashes on the reflector plate are destroyed at a temperature of 500° C. or above and the Mg steam is routed, by means of a channel heated to at least 500° C., from the outlet of the receptacle to a substrate sheet positioned at the channel exit. In addition, the Mg steam is conveyed through the channel from the outlet of the receptacle to a substrate sheet.

Generally speaking, a distinction is drawn between static systems and continuous systems. With the static method, the delivery of the substrate is intermittent, and the regular replacement of the substrate enables regular stocking up with new coating material for the subsequent coating process, while with the continuous method a substrate is conveyed continuously through the coating device. In order not to interrupt the continuous process and for the use of such a device to be economic, it is necessary to supply the coating device with sufficient coating material to coat without interruption at least a substrate unit, for example a reel.

The scale of the vaporization device, i.e. the quantity of vaporized coating material per time unit, is directly connected with the size and conveying speed of the substrate; in addition, a high use of steam requires a much larger, i.e. higher, deposition chamber. In this respect, profitability is connected directly with the size of the system and also with the size of the vaporization device, which limits the continuous coating systems described due to the supply of the coating material and the profitability associated with them.

In systems with continuous substrate conveyance, it has hitherto been regarded as expedient to arrange the vaporization device in the deposition chamber due to the smaller substrate measurements and the fact that controlling it is simpler as a result. However, there are many disadvantages to this approach especially with larger substrate measurements. Due to the extensive spatial requirements of the dimensions of the vaporization device, an economically advantageous system has extensive scope in terms of expansion over a level plain.

In particular, controlling the processes taking place in the deposition channel and vaporization device independently of each other is not sufficiently possible due to the proximity of these to each other. Maintenance work on the vaporization device inevitably requires the system to be stopped and is also awkward and involved, as the vaporization device is an integral component and not easily accessible. In addition, it is not possible to alter the vaporization device by modifying components or adding additional modules to it. Furthermore, a continuous supply of coating material, which is needed particularly with the coating of continuously conveyed substrate, is only possible at considerable expense.

The aim of this invention is therefore to create a coating method and coating device for thermally vacuum-depositing a continuously conveyed substrate, in which accessibility to the vaporization device is improved while the processes taking place in the deposition chamber and vaporization device can be controlled independently of each other.

In accordance with the method which has been invented, this aim has been achieved by vaporizing the coating material in at least one vaporization device located outside the deposition chamber by means of an evaporator, the delivery of steam between the evaporator and the deposition channel being regulated.

The invention covers every suitable, at least steam-tight, regulating option. Accordingly, a simple sealing plate could also be used, for example, due to the restriction that the regulatory function is steam-tight, and in this case the regulation is limited to the states open and closed.

The location of the vaporization device outside the deposition chamber allows, in connection with the regulatory option proposed by this invention, which also implies the complete closure of the steam release opening, access to the evaporator while at the same time maintaining the process conditions in the deposition channel. The substrate can thus remain in the deposition channel while the evaporator, for example, is supplied with new coating material.

Furthermore, this spatially separate location of the vaporization device and deposition chamber also enables independent control of the processes, particularly in terms of the vacuum conditions and the temperature regime, because as a result of this the individual control elements of the process conditions can also be spatially separated or at least there is the choice of implementing them in a spatially separate manner. The steam-tight regulation of the connection between the two main constituent parts of the coating system in particular and the possibility of a separate opening due to this also requires the vacuum conditions to be controlled independently.

The regulation of the steam delivery is expedient, in accordance with a particularly convenient arrangement of the invention, via a steam trap valve located next to the evaporator on the outlet side. The regulation in this respect affects both the switching between outlet and no outlet and the dosing of the amount of steam. In addition, it is also possible to dose the vaporization quantity by regulating the process pressure and the temperature.

One design of the invention provides for the vaporized coating material to be routed from the evaporator into a steam collection device in the vaporization device.

Especially in the case of multiple, i.e. three, four, five or more evaporators per vaporization device, it is advantageous in terms of equal steam dosage to combine the vaporized coating material from each deposition chamber in operation and from this combined volume to be routed into the deposition chamber. In this way, if the measured volume of the steam collection device is sufficiently large, it is possible to compensate for fluctuations in the steam supply or even interruptions caused by new charging. To this end, the steam collection device will also be evacuated and heated in addition, so that the vaporized coating material cannot precipitate on the walls.

It is preferable that for continuous charging the vaporized coating material is conveyed from the evaporator to the deposition chamber, and that for charging with the solid or liquid coating material, the delivery of steam between the evaporator and the deposition channel is prevented.

It is particularly expedient for at least two evaporators to be located and for their steam trap valves to be controlled independently of each other.

In the case of several evaporators, a graded dosing by means of the number of open evaporators, thus in operation in the vaporization process, is thus achieved, which also permits special substrate locations or special coating profiles to be taken into account, in addition to the particularly uniform delivery of steam to the deposition channel which is relatively independent of the current operating state of individual evaporators.

However, the band-shaped substrate, when in operation, generally extends symmetrically by and large through the deposition channel. For continuous charging of the deposition channel at least one evaporator must be in operation in turn, in line with a particularly advantageous arrangement and must be located with the deposition channel in the steam supply, while for charging with the new coating material the steam supply of the evaporator to be charged is prevented. This results in an economically advantageous, permanent and continuous deposition process.

For larger coating surfaces per time unit, another version of the invention for continuous charging of the deposition channel contains four evaporators, of which three alternately are always connected with the vaporized coating material in the steam supply with the deposition channel, and with which, when charging with the solid and/or liquid coating material, the steam supply to the evaporator to be charged is prevented. In this case, the provision of even larger amounts of vaporized coating is guaranteed by all the evaporators being in operation and only one is ever being charged with new coating material.

An arrangement of four or more evaporators in one vaporization device also offers greater flexibility in terms of use as well as the option of extending it with additional evaporator modules.

In one particularly advantageous design, the charging of the deposition channel with the vaporized coating material takes place using two vaporization devices. The deposition channel in this case is supplied from two, preferably opposite, sides with the vaporized coating material. The coating material enters from different directions and this produces optimum distribution in the deposition channel.

In another extension of the design of the invention, the charging of the deposition channel with the vaporized coating material is achieved via one steam conveyance line arranged between the deposition channel and the vaporization device. The specifications of the conveyance line to guarantee an equal and sufficient supply of vaporized coating material is achieved corresponding to the necessary throughput by the conveyance line to the deposition channel, which on the one hand is specified by the quantity of the coating material vaporized in the vaporization device and occurring on the side of the evaporator in the conveyance line, and on the other hand by the quantity of the condensed, thus smaller in terms of volume, coating material occurring at the other end of the conveyance line in the deposition channel and on the substrate. The quantity of condensate is defined by the width and conveyance speed of the substrate as well as by the physical process parameters.

In terms of its arrangement, the basic aim of the invention has been solved by arranging the vaporization device at a distance from the deposition chamber. This spatial separation enables optimum constructional separation of the two main components of the system and enables them to be laid out in modular fashion. In the case of several evaporators in particular, this enables a further arrangement of the invention, the spatial division of which, so that the required connected base for the core component of the coating device, namely the deposition chamber, is essentially reduced in size to the size of the deposition chamber necessary for deposition. The vaporization device is set up at a distance from the deposition chamber and, if necessary, positioned satellite-like at different locations within the available free space and, in line with a particularly favorable arrangement of the invention, connected with the deposition chamber using one or more steam conveyance lines.

To minimize material losses and to guarantee that the coating conditions can be reproduced, the steam conveyance lines or conveyance lines are, as with the steam collection device and deposition chamber, operated in a vacuum and heated, whereby the heating is preferably complete. A sufficiently high temperature on the heated inside wall will cause any steam hitting the inner wall in the current process to be reverse-vaporized, and the higher the temperature of the inner wall, the greater this effect. The steam conveyance line is attached in a steam-tight manner between the deposition channel and the vaporization device. If the vaporization device includes a steam collection device in line with another advantageous design form, the steam conveyance line is connected there. This is so that the various amalgamations and, alternatively, connections described above, can also be implemented over spatial distances.

For this reason, the steam collection device is located centrally between the evaporators and connected with these on the one hand and at least indirectly connected with the deposition device on the other hand. The steam collection device can be heated, preferably to its full extent, and can also be evacuated.

Locating several, e.g. four, evaporators in one vaporization device offers a high degree of flexibility in terms of use and with evaporators active, i.e. in operation, a large quantity of vaporized coating material. Two vaporization chambers stand on each side of the elongated design of the steam collection device directly opposite one another. The vaporization chambers stretch advantageously crosswise to the elongated steam collection device. It is expedient that the steam collection device and the evaporators are connected with each other via steam trap valves.

The invention shall be described in more detail in the following using a design example. In the accompanying drawing, the drawing figure shows a detail of a horizontal cross section through a coating device, in line with the invention, with an external vaporization device.

With regard to the object:

The drawing figure shows a coating device 1 in accordance with the invention with a deposition chamber 2 and, at a distance from it, an external vaporization device 3. The deposition chamber 2 is connected with the vaporization devices 3, in each case with a steam conveyance line 4, whereby the vaporization device 3 is located on the steam conveyance line 4.

The vaporization device 3 comprises a channel-like central steam collection device 5 and four evaporators 6. The evaporators 6 stretch laterally from the steam collection device 5 and are arranged in pairs opposite each other on one level by the steam collection device 5.

Each vaporization chamber 8 includes an evaporator 6 heatable by an electric heating device 7. There is a process vacuum inside the vaporization chamber 8 and the evaporator 6.

There is a crucible 9 located inside the evaporator with solid coating material 10, for example magnesium. The evaporator 6 is connected with the steam collection device 5 via a controllable steam trap valve 11.

The vapor collection device 5 is shaped as a tube-like channel and is completely surrounded by an electric heating device 7. The deposition chamber end of the steam conveyance line 4 leads into the deposition channel 13 and is shaped as a nozzle 12.

The nozzle 12 enters on one side of the deposition channel 12, which is shaped as a cuboid hollow on the inside. A band-shaped substrate 14 is conveyed into the deposition channel 13 when in operation - this is arranged symmetrically in the hollow cuboid-shaped deposition channel 13. The nozzle 12 enters the deposition channel 12 at the middle point. A heating device 7 is attached all around the deposition channel 13.

The coating device 1, in accordance with the invention, thus has a completely closed vacuum chamber from the three vaporization chambers 8 via the steam conveyance line 4 through to the deposition chamber 2.

With regard to the method:

The coating method is a continuous thermal vacuum-depositing of the band-shaped substrate 14 by vaporizing solid magnesium as the coating material 10 and vapor- depositing the vaporized coating material 10 on the continuously conveyed substrate 14 and deposition channel 13.

Each vaporization chamber 8 is evacuated with the solid coating material 10 and the evaporator 6 is heated sufficiently. When the coating material 10 is vaporized, the steam trap valve 11 opens and provides access into the steam collection device 5. Due to the increase in volume when the coating material 10 changes from a solid into its vaporized form, other vaporized coating material 10 continuously pushes forward from behind and the conveyance device passes forward.

During the vaporization process, three of the four evaporators 6 are always in operation, i.e. the steam trap valves 11 are open and solid coating material 10 is turned to vaporized material. The fourth evaporator 6 in each case is not in operation and the crucible 9 is charged with more solid coating material 10, then the evaporator 6 is evacuated and heated up. When this evaporator 6 is ready for operation, the steam trap valve 11 opens and another of the three evaporators 6 is taken out of operation and charged. The rotation cycle varies.

The vaporized coating material 10 which comes from the in-operation evaporators 6 of an vaporization device 3 through the steam trap valves into the steam collection space 5, which is also heated, streams through the sufficiently heated steam conveyance line 4 and is accelerated through the nozzle 12, which is also sufficiently heated, and carried into the deposition channel 13. By selecting a suitable heating

temperature, which depends on the coating material 10, and with it the surface temperature of the evaporators 6, steam collection device 5, steam conveyance line 4, nozzle 12 and deposition channel 13, the vaporized coating material 10 deposited on the inside walls is reverse-vaporized so that a deposit of solid coating material 10 on the inside walls is prevented.

The vaporized coating material 10 which has entered the sufficiently heated and also evacuated deposition channel 13 is deposited on the cold band-shaped substrate 14 conveyed through the deposition channel 13.

The coating method of this invention provides a completely continuous process with an extremely high degree of vapor use.

### Continuous Thermal Vacuum Deposition Device and Method

### List of Numerals

1. Coating device
2. Deposition chamber
3. Vaporization device
4. Steam conveyance line
5. Steam collection device
6. Evaporator
7. Heating device
8. Vaporization chamber
9. Crucible
10. Coating material
11. Steam trap valve
12. Nozzle
13. Deposition channel
14. Substrate

1. Coating method for thermally vacuum-depositing a continuously conveyed substrate, that moves within a deposition channel, by vaporizing solid and/or liquid coating materials and vapor-depositing the vaporized coating material onto the substrate in a deposition device, wherein the coating material is vaporized in at least one vaporization device located outside the deposition chamber with at least two evaporators per vaporization device, and delivery of steam between the evaporators and deposition channel is regulated, and wherein, for continuous charging of the deposition chamber with the vaporized coating material, the evaporators alternate in delivering steam to the deposition channel, and for charging with the solid and/or liquid coating material the delivery of steam of an evaporators to be charged is prevented.

2. Coating method in accordance with claim 1, wherein steam delivery regulation is achieved using a steam trap valve located by an outlet on the evaporator.

3. Coating method in accordance with claim 1, wherein the vaporized coating material from the evaporator is routed into a steam collection device, which is part of the vaporization device.

4. Coating method in accordance with claim 1, wherein, for the continuous charging, the vaporized coating material is conveyed from the evaporator to the deposition channel and for charging with the solid and/or liquid coating material, the delivery of steam between the evaporator and the deposition channel is prevented.

5. Coating method in accordance with claim 2, wherein steam trap valves equal in number to the evaporators are provided, and the steam trap valves are controlled independently of each other.

6. Coating method in accordance with claim 5, wherein for continuous charging of the deposition device, four evaporators are provided and with the coating material, three out of four of the evaporators always take turns in delivering steam to the deposition channel, and for charging with the solid and/or liquid coating material, the delivery of steam from the evaporator to be charged is prevented.

7. Coating method in accordance with claim 1, wherein the charging of the deposition channel with the vaporized coating material is achieved via a steam conveyance line located between the deposition channel and the vaporization device.

8. Coating method in accordance with claim 1, wherein the charging of the deposition channel with the vaporized coating material is achieved via two vaporization devices.

9. Coating device for thermal vacuum deposition of a continuously conveyed substrate comprising a deposition chamber, in which is located a deposition channel enclosing the substrate, and a vaporization device connected with the deposition channel, wherein the vaporization device is located at a distance from the deposition chamber and the vaporization device contains at least two evaporators connected with the deposition channel using a heated steam conveyance line, and wherein the steam collection device is connected with each of the evaporators using a vacuum-tight closing steam trap valve.

10. Coating device in accordance with claim 9, wherein the vaporization device includes a vapor collection device.
